(19) United States
(12) Patent Application Publication
(10) Pub. No.: US 2025/0105105 A1
(43) Pub. Date: Mar. 27, 2025

(54) SEMICONDUCTOR DEVICE

(71) Applicant: LAPIS Semiconductor Co., Ltd., Yokohama (JP)

(72) Inventors: Ryo SEKIKAWA, Kouhoku-ku (JP); Isao KURITA, Kouhoku-ku (JP); Yuichi YOSHIDA, Kouhoku-ku (JP)

(73) Assignee: LAPIS Semiconductor Co., Ltd., Yokohama (JP)

(21) Appl. No.: 18/895,117

(22) Filed: Sep. 24, 2024

(30) Foreign Application Priority Data
Sep. 27, 2023 (JP) 2023-165987

(51) Int. Cl. H01L 23/495; H01L 23/31

(52) U.S. Cl. CPC H01L 23/49548; H01L 23/3107

(57) ABSTRACT

Provided is a semiconductor device that can suppress flash/burrs from forming on a lower surface of a die pad in a configuration in which the lower surface of the die pad is exposed from a sealing resin. The semiconductor device includes a lead frame, a semiconductor chip, and a sealing body. The lead frame includes a plate-shaped die pad and a lead. The die pad has one principal surface with a mounting region for mounting the semiconductor chip. The die pad includes a side portion and a frame-shaped protrusion on the side portion in top view. The protrusion overhangs in a lateral direction in an eave shape along the one principal surface. The semiconductor chip is mounted on the mounting region. The sealing body covers a side surface of the die pad while exposing the other principal surface of the die pad and sealing the semiconductor chip on the one principal surface of the die pad. The sealing body holds the die pad and the lead. The die pad has a through hole penetrating the protrusion in a direction intersecting with the one principal surface.

### BACKGROUND

### 1. Technical Field

The present disclosure relates to a semiconductor device.

### 2. Description of the Related Art

A semiconductor device including a lead frame with a die pad and leads, a semiconductor chip mounted on the die pad, and a sealing resin sealing the lead frame and the semiconductor chip is disclosed. For example, JP-A-2011-082446 discloses a semiconductor device in which a lower surface of a die pad is exposed from a sealing resin and has a groove portion with a plurality of grooves formed on the lower surface.

In the semiconductor device described in JP-A-2011-082446, for example, when the die pads and the leads with the mounted semiconductor chips are installed on a mold and a sealing resin is injected into the mold during the manufacturing of the semiconductor devices, the sealing resin is guided along the grooves formed on the lower surface of the die pads.

However, depending on a pressure when the sealing resin is injected, it is possible that the sealing resin may flow into areas other than the grooves between the mold and the lower surfaces of the die pads, that is, areas that are intended to be exposed by the sealing resin.

If this happens, the resin that adheres to the areas other than the grooves on the lower surface of the die pad will harden and remain as flash/burrs, which will reduce a heat dissipation property when attempting to dissipate heat generated in the semiconductor chip when driving the semiconductor chip, for example.

The present disclosure has been made in consideration of the above-described points, and its objective is to provide a semiconductor device that can suppress flash/burrs from forming on a lower surface of a die pad in a configuration in which the lower surface of the die pad is exposed from a sealing resin.

### SUMMARY

A semiconductor device according to the present disclosure includes a lead frame, a semiconductor chip, and a sealing body. The lead frame includes a plate-shaped die pad and a lead. The die pad has one principal surface with a mounting region for mounting the semiconductor chip. The die pad includes a side portion and a frame-shaped protrusion on the side portion in top view. The protrusion overhangs in a lateral direction in an eave shape along the one principal surface. The semiconductor chip is mounted on the mounting region. The sealing body covers a side surface of the die pad while exposing the other principal surface of the die pad and sealing the semiconductor chip on the one principal surface of the die pad. The sealing body holds the die pad and the lead. The die pad has a through hole penetrating the protrusion in a direction intersecting with the one principal surface.

### BRIEF DESCRIPTION OF THE DRAWINGS

FIG. 1 is a top view of a semiconductor device according to Embodiment 1;

FIG. 2 is a cross-sectional view of the semiconductor device according to Embodiment 1;

FIG. 3 is a cross-sectional view illustrating a state of a resin injection during a manufacturing of the semiconductor device according to Embodiment 1;

FIG. 4 is a top view of a semiconductor device according to Modification 1 of Embodiment 1; and

FIG. 5 is a top view of a semiconductor device according to Modification 2 of Embodiment 1.

### DETAILED DESCRIPTION

The following embodiment of the present disclosure is described with reference to the drawings. In the description and attached drawings of the embodiment below, same reference numerals are given to approximately the same or equivalent parts.

### Embodiment 1

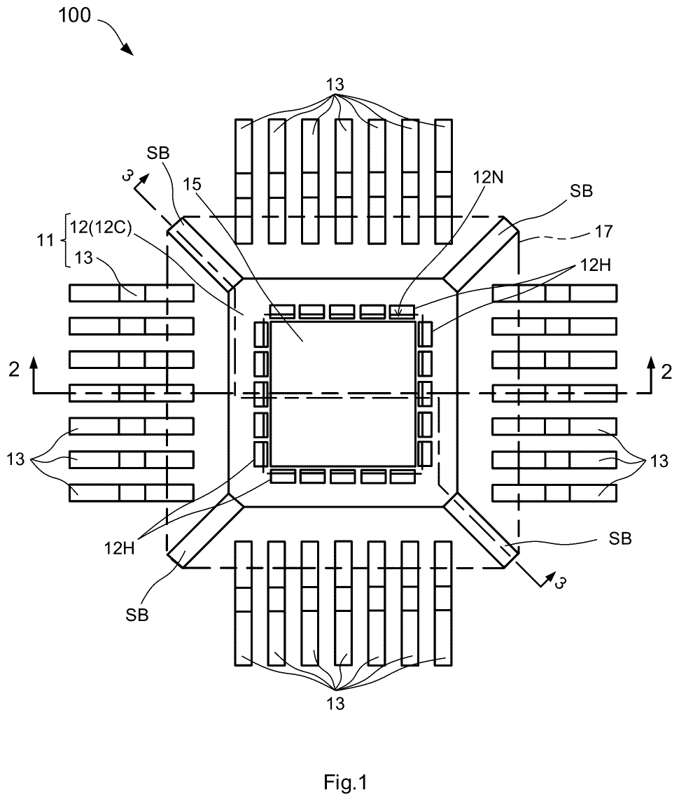

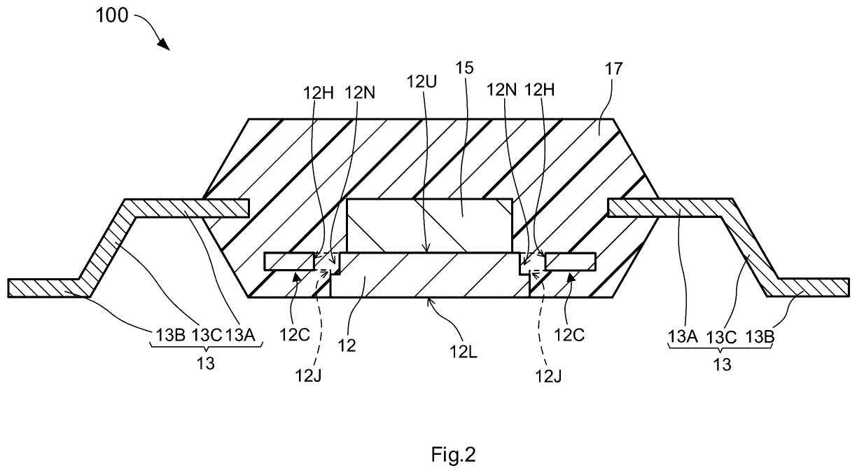

Using FIGS. 1 and 2, a structure of a semiconductor device 100 according to Embodiment 1 is described. FIG. 1 is a top view of the semiconductor device 100. FIG. 2 is a cross-sectional view of the semiconductor device 100 illustrated in FIG. 1 along the 2-2 line. In FIG. 2, the vertical direction in the figure is the height direction of the semiconductor device 100. In FIG. 1, for the sake of clarity, an outer edge of a sealing body 17, which will be described later, is illustrated with a long dashed double-short dashed line, and the other structural members sealed by the sealing body 17 are illustrated as solid lines.

A lead frame 11 is constituted of a die pad 12 that holds a semiconductor chip 15, which will be described later, and leads 13 that are used as wiring when mounting the semiconductor device 100. The lead frame 11 is made of a metal material, such as copper (Cu), iron (Fe), or an alloy based on these.

The die pad 12 is a plate-shaped body having a rectangular upper surface shape. The die pad 12 has a protrusion 12C on its side portion that laterally overhangs in an eave shape along an upper surface 12U thereof and has a frame shape in top view. In other words, the die pad 12 has an eave-shaped portion that laterally overhangs from the side portion of the die pad 12 along the upper surface 12U. This protrusion 12C is formed in a frame shape in top view.

The die pad 12 has through holes 12H that penetrate a portion of a base 12J of the protrusion 12C described above in the direction of height. In the semiconductor device 100 of this embodiment, the through hole 12H has a rectangular upper surface shape with the direction along each side of the die pad 12 as the longitudinal direction, and the plurality of through holes 12H are formed along each of the sides of the die pad 12. In this embodiment, five through holes 12H are provided along each of the sides of the die pad 12.

The through hole 12H has a notch 12N that terminates from a portion inside the base 12J of the protrusion 12C on the upper surface 12U of the die pad 12 in the height direction, without reaching a lower surface 12L of the die pad 12. In the through hole 12H, the cutout portion due to the notch 12N is exposed in top view (see FIG. 1).

In other words, the through hole 12H has a cross-sectional shape that penetrates the portion of the base 12J of the protrusion 12C of the die pad 12, as illustrated in FIG. 2, and includes a step portion in the portion inside the base 12J of the through hole 12H.

The through hole 12H with a cross-sectional shape like this can be formed, for example, by etching the portion of the base 12J of the protrusion 12C in the die pad 12 to a depth that does not reach the lower surface 12L from the upper surface 12U side. The through hole 12H may also be formed by a method other than the etching, such as a mechanical processing such as drilling.

As illustrated in FIG. 1, the die pad 12 is provided with support bars SB with rectangular upper surface shapes that extend outward along diagonal lines of the die pad 12 from respective four corners of the frame-shaped protrusion 12C. The support bars SB are used as guides when injecting a mold resin 17M, which will be described later, during the manufacture of the semiconductor device 100.

The leads 13 are long, narrow, thin plates that are arranged in a direction that are separated from one another along each side of the upper surface 12U of the die pad 12 in top view. In other words, the leads 13 are arranged along each side of the die pad 12 in top view so as to surround the die pad 12. In FIG. 1, the seven leads 13 are provided for each side.

As illustrated in FIG. 2, the lead 13 includes: a first parallel portion 13A that extends in a direction parallel to the upper surface 12U, which is disposed on one end, that is, a proximal side with respect to the die pad 12; a second parallel portion 13B that extends in the direction parallel to the upper surface 12U, which is disposed on the other end, that is, a distal side with respect to the die pad 12 and below the first parallel portion 13A; and a sloping portion 13C that slopes to connect the first parallel portion 13A and the second parallel portion 13B.

The second parallel portion 13B of the lead 13 is a portion that is joined to a printed circuit board using a bonding material such as solder when, for example, the semiconductor device 100 is mounted on the printed circuit board.

The semiconductor chip 15 has a rectangular upper surface shape and is a semiconductor element, such as an IC chip, made of a semiconductor material, such as silicon (Si). The semiconductor chip 15 is mounted on a mounting region (not illustrated) of the upper surface 12U of the die pad 12 using a bonding material such as solder (not illustrated).

On the top surface of the semiconductor chip 15, the electrode pads (not illustrated) are formed in the number of the leads 13, and each of the electrode pads of the semiconductor chip 15 is electrically connected to each of the leads 13 via a wire (not illustrated) made of metal such as gold (Au) and aluminum (Al).

The sealing body 17 is a sealing member made of a resin such as epoxy resin that partially covers the die pad 12 and the leads 13, so as to seal the semiconductor chip 15 mounted on the die pad 12 while holding the die pad 12 and the leads 13.

Specifically, the sealing body 17 covers side surfaces of the die pad 12 while exposing the lower surface 12L of the die pad 12, and seals the semiconductor chip 15 on the upper surface 12U of the die pad 12 to hold the die pad 12, and also holds the leads 13 by covering portions of the first parallel portions 13A of the leads 13.

In other words, in the semiconductor device 100, the lower surface 12L of the die pad 12 and the first parallel portions 13A of the leads 13 excluding the portions thereof are exposed from the sealing body 17, and the rest is sealed by the sealing body 17.

As described above, the semiconductor device 100 receives electrical supply from an external power supply connected to the printed circuit board by, for example, the second parallel portions 13B of the leads 13 being electrically connected to the printed circuit board.

In the semiconductor device 100 mounted on the printed circuit board, the lower surface 12L of the die pad 12 is exposed from the sealing body 17. Thus, the heat generated when the semiconductor chip 15 is driven by receiving the electrical supply can be dissipated to outside via the lower surface 12L of the die pad 12. In other words, the semiconductor device 100 has a structure that is intended to dissipate the heat generated when the semiconductor chip 15 is driven via the die pad 12.

For example, the heat dissipation of the semiconductor device 100 may be achieved by connecting the lower surface 12L of the die pad 12 to a heat dissipation structure that dissipates heat to the outside of the device to which the semiconductor device 100 is attached via a heat conduction member such as metal.

### [Mechanism for Suppressing Formation of Flash/Burrs on the Lower Surface of the Die Pad]

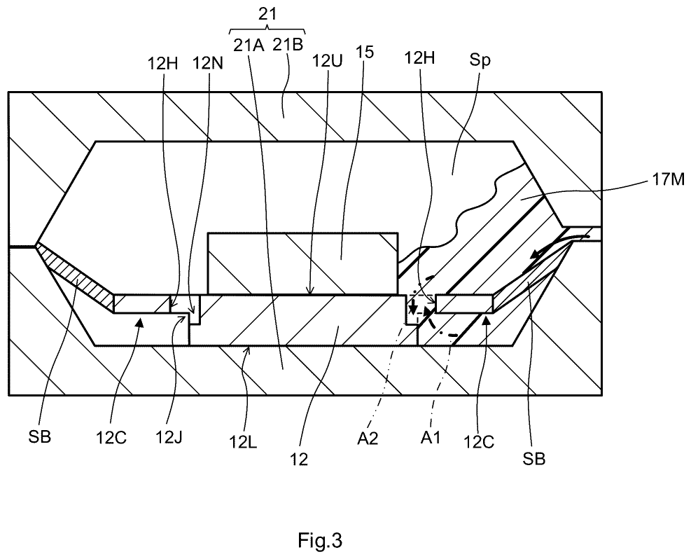

Here, using FIGS. 1 to 3, it is described how to suppress the formation of the flash/burrs on the lower surface 12L of the die pad 12 during the manufacture of the semiconductor device 100. FIG. 3 is a cross-sectional view of the semiconductor device 100 along the 3-3 line in FIG. 1, and illustrates a state of a mold resin being injected when the sealing body 17 is formed during the manufacture of the semiconductor device 100.

When manufacturing the semiconductor device 100, as illustrated in FIG. 3, in a state where the die pad 12, on which the semiconductor chip 15 is mounted, is held by a mold 21, and the mold resin 17M, which is the sealing body 17 before hardening, is injected.

Specifically, the die pad 12, on which the semiconductor chip 15 is mounted, is disposed on a lower mold 21A of the mold 21, and each of the leads 13 is secured in a manner where it is sandwiched between an upper mold 21B and the lower mold 21A of the mold 21. Then, the mold resin 17M is injected into a sealing space SP formed by the lower mold 21A and the upper mold 21B, and the sealing body 17 in the semiconductor device 100 is formed by hardening of the mold resin 17M.

The mold resin 17M is supplied into the sealing space SP at a predetermined pressure via the support bars SB through a gate (not illustrated) provided in the mold 21, as illustrated by a solid arrow in FIG. 3, for example. The mold resin 17M is injected from a lower right corner portion of the die pad 12, which is close to the gate described above, and runs around to an upper left corner portion, which is on the diagonal line of the lower right corner portion.

As described above, in the semiconductor device 100 of this embodiment, the through holes 12H are formed at the portion of the base 12J of the protrusion 12C of the die pad 12. This suppresses the flash/burrs from forming on the lower surface 12L by the mold resin 17M entering under the lower surface 12L of the die pad 12 when the mold resin 17M is injected into the sealing space SP.

The following describes a specific mechanism by which the formation of flash/burrs is suppressed. When the mold resin 17M is injected into the sealing space SP described above, the mold resin 17M enters, for example, a space below the protrusions 12C. For example, when the die pad 12 did not have the through holes 12H in the protrusion 12C, the mold resin 17M having entered the space below the protrusion 12C would not have almost no escape route to a space above the protrusion 12C. Thus, a momentum can be concentrated on the lower end of the die pad 12.

Accordingly, if the through holes 12H were not formed in the protrusion 12C of the die pad 12, the pressure of the mold resin 17M applied to the lower end of the die pad 12 could cause the resin to enter between the lower surface 12L of the die pad 12 and the lower mold 21A from the lower end for causing the die pad 12 to lift up. Thus, there is a risk that the lower surface 12L possibly separates from the lower mold 21A. There is also a risk that the resin having entered under the protrusions 12C of the die pad 12 possibly push the protrusion 12C upward, causing the die pad 12 to lift up.

For example, if the injected mold resin 17M entered between the lower surface 12L of the die pad 12 and the lower mold 21A, the flash/burrs could be formed on the lower surface 12L of the die pad 12 as the mold resin 17M hardens in that state.

For example, if the flash/burrs were formed on the lower surface 12L of the die pad 12, the heat dissipation property of the lower surface 12L of the die pad 12 would be reduced when driving the semiconductor chip 15 as described above, and this could in turn lead to an increase in temperature of the semiconductor chip 15 and cause a failure. Also, for example, if there is a lot of flash/burrs remaining on the lower surface 12L of the die pad 12, there is a risk that the effort required to remove the flash/burrs in order to ensure the heat dissipation property will increase.

According to the semiconductor device 100 of this embodiment, as described above, the through holes 12H are formed in the protrusion 12C of the die pad 12. Thus, the pressure applied to the lower end of the die pad 12 is released when the mold resin 17M is injected. This suppresses the mold resin 17M from entering between the lower surface 12L of the die pad 12 and the lower mold 21A.

Specifically, in the semiconductor device 100 of this embodiment, the mold resin 17M is also allowed to flow around the lower side of the protrusion 12C and through the through holes 12H from the lower side of the protrusion 12C to the upper surface 12U side of the die pad 12, as illustrated by the long dashed short dashed arrow A1 in FIG. 3. This allows the pressure during the injection of the mold resin 17M to be dispersed via the through holes 12H, suppressing the pressure of the mold resin 17M from concentrating at the lower end of the die pad 12.

Accordingly, in the semiconductor device 100 of this embodiment, the pressure at the time of the injection of the mold resin 17M is dispersed, and this suppresses the mold resin 17M from entering between the lower surface 12L of the die pad 12 and the lower mold 21A.

In addition, as described above, according to the semiconductor device 100 of this embodiment, the through holes 12H have the notches 12N that terminate from the portion inside the base 12J of the protrusion 12C in the height direction without reaching the lower surface 12L of the die pad 12.

Accordingly, in the semiconductor device 100 of this embodiment, when, for example, the mold resin 17M flows into the through holes 12H from the upper surface 12U side of the die pad 12, the mold resin 17M hits the step portions formed by the above-described notches 12N, as illustrated by the long dashed double-short dashed arrow A2 in FIG. 3. Thus, the pressure of the mold resin 17M is applied in the downward direction in FIG. 3, and the effect of restraining the die pad 12 from the top side can also be achieved.

Accordingly, in the semiconductor device 100 of this embodiment, the die pad 12 restrains down from above, which makes it difficult for the lower surface 12L of the die pad 12 to lift up from the lower mold 21A, and suppresses the mold resin 17M from entering under the lower surface 12L of the die pad 12.

Accordingly, in the semiconductor device 100 of this embodiment, the through holes 12H formed in the die pad 12 allow the pressure of the mold resin 17M supplied from below the protrusion 12C of the die pad 12 to be released, while also allowing the restraining effect by the mold resin 17M supplied from above the protrusion 12C to be obtained.

Accordingly, in the semiconductor device 100 of this embodiment, in the configuration in which the lower surface 12L of the die pad 12 is exposed from the sealing body 17 as the sealing resin, it is possible to suppress the formation of the flash/burrs on the lower surface 12L of the die pad 12.

In the semiconductor device 100 of this embodiment, the through holes 12H formed in the protrusion 12C of the die pad 12 have the rectangular upper surface shapes, but this is not limited thereto, and they may have other shapes. For example, the through hole 12H may have a round or oval upper surface shape.

In the semiconductor device 100 of this embodiment, the through holes 12H formed in the protrusion 12C of the die pad 12 penetrate the protrusion 12C in the height direction, but it is not necessary to be formed in the direction perpendicular to the upper surface 12U of the die pad 12.

For example, the through holes 12H may be formed at an angle with respect to the upper surface 12U of the die pad 12. For example, the through holes 12H may be formed such that a diameter of the lower surface 12L side of the die pad 12 becomes larger than a diameter of the upper surface 12U, or vice versa. In other words, the through holes 12H may be formed to have an approximately trapezoidal cross-sectional shape.

In other words, the through holes 12H may be formed to intersect with the upper surface 12U of the die pad 12. Even when the through holes 12H are formed in this way, it is possible to release the pressure of the mold resin 17M supplied from below the protrusion 12C of the die pad 12, while also allowing the restraining effect by the mold resin 17M supplied from above the protrusion 12C to be obtained.

In the semiconductor device 100 of this embodiment, the number of the through holes 12H formed in the protrusions 12C of the die pad 12 is assumed to be five along each side of the die pad 12, but this is not limited thereto, and for example, the number may be increased or decreased depending on the size of the die pad 12.

In the semiconductor device 100 of this embodiment, the through holes 12H formed in the protrusions 12C of the die pad 12 are not limited to being formed along each side of the die pad 12 in top view. For example, it may also be possible to form the through holes 12H only on the two sides of the die pad 12 close to the gate for injecting the mold resin 17M, that is, only on the right side and the lower side of the die pad 12 in the case of FIG. 1.

In the semiconductor device 100 of this embodiment, it is assumed that the support bar SB is provided at each of the four corners of the die pad 12, but it is not necessary to provide the support bar SB at each of the four corners. It is also possible to provide the support bar SB only at the corner portion of the die pad 12 closest to the gate described above.

In the semiconductor device 100 of this embodiment, the through hole 12H has the notch 12N that terminates from the portion inside the base 12J of the protrusion 12C on the upper surface 12U of the die pad 12 without reaching the lower surface 12L of the die pad 12 in the height direction, but it is not necessary to have this notch 12N. For example, the through hole 12H may be formed in a position distant from the base 12J of the protrusion 12C, that is, so as to penetrate only the protrusion 12C.

### [Modification 1]

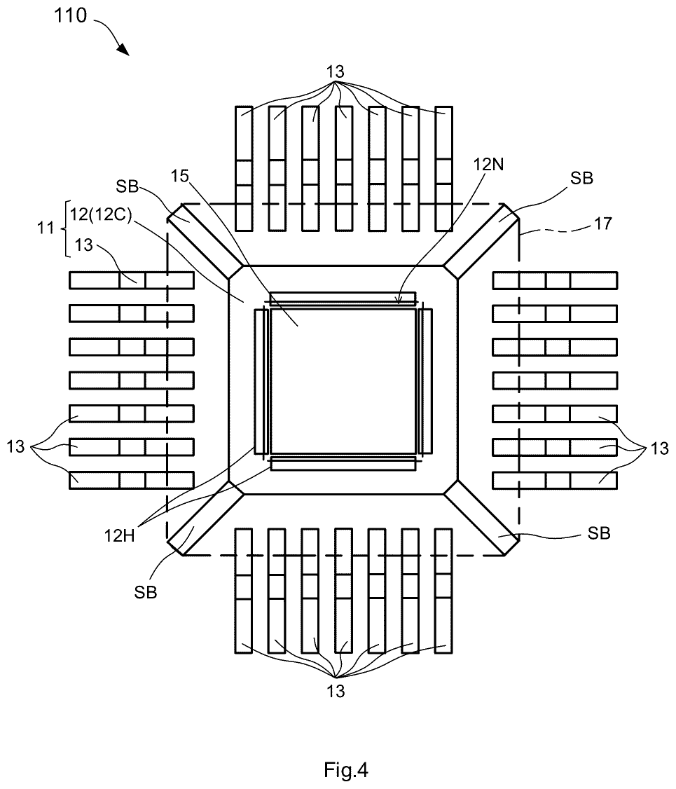

The following describes Modification 1 of the semiconductor device 100 according to Embodiment 1. FIG. 4 is a top view of a semiconductor device 110 according to Modification 1. The semiconductor device 110 has a through hole 12H with a shape different from that of Embodiment 1, and is otherwise the same as Embodiment 1.

In the semiconductor device 110 of this modification, the through hole 12H has a rectangular shape with the direction along each side of the semiconductor chip 15 as the longitudinal direction, and the length of the longitudinal direction is the same length as the side of the semiconductor chip 15.

In other words, in the semiconductor device 110, one through hole 12H is formed along each side of the semiconductor chip 15. Therefore, in the semiconductor device 110 of this modification, the through hole 12H has a larger area than the through hole 12H illustrated in Embodiment 1.

Even when the through hole 12H is formed in this way, the through hole 12H formed in the die pad 12 releases the pressure of the mold resin 17M supplied from below the protrusion 12C of the die pad 12 and obtains the effect of restraining by the mold resin 17M supplied from above the protrusion 12C.

Accordingly, in the semiconductor device 110 of this modification, as in Embodiment 1, in the configuration where the lower surface 12L of the die pad 12 is exposed from the sealing body 17, the formation of the flash/burrs on the lower surface 12L of the die pad 12 can be suppressed.

In the semiconductor device 110 of this modification, the through holes 12H may be formed in a manner where the respective holes are formed in a continuous manner. In other words, the through holes 12H may be formed such that they have a frame-shaped appearance in top view.

### [Modification 2]

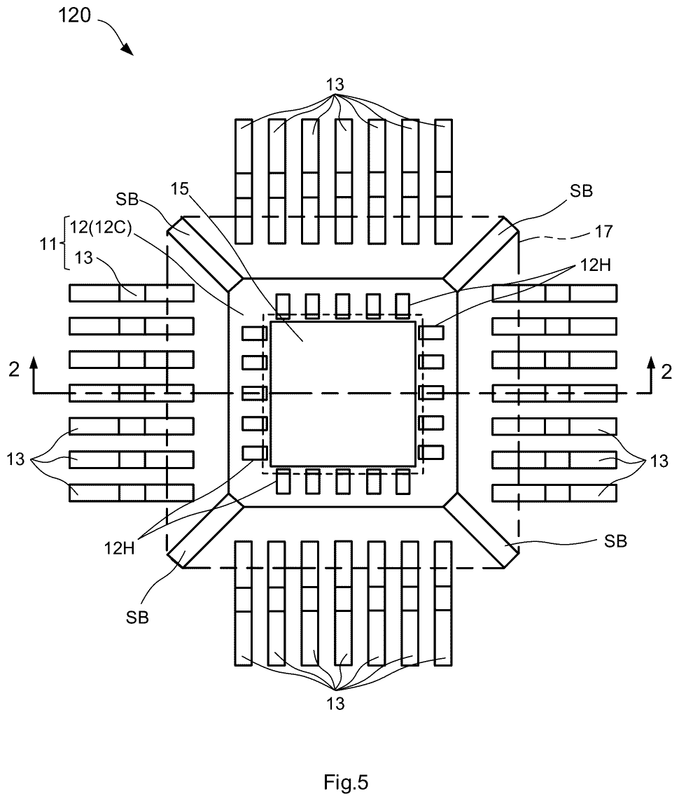

The following describes Modification 2 of the semiconductor device 100 according to Embodiment 1. FIG. 5 is a top view of a semiconductor device 120 according to Modification 2. The semiconductor device 120 has a through hole 12H with a shape different from that of Embodiment 1, and is otherwise the same as Embodiment 1.

In the semiconductor device 120 of this modification has a through hole 12H whose longitudinal direction and short direction are opposite to those of the through hole 12H illustrated in Embodiment 1. In other words, in the semiconductor device 120, the through hole 12H has a longitudinal direction perpendicular to the direction along the side of the die pad 12.

Even when the through hole 12H is formed in this way, the through hole 12H formed in the die pad 12 releases the pressure of the mold resin 17M supplied from below the protrusion 12C of the die pad 12 and obtains the effect of restraining by the mold resin 17M supplied from above the protrusion 12C.

Accordingly, in the semiconductor device 120 of this modification, as in Embodiment 1, in the configuration where the lower surface 12L of the die pad 12 is exposed from the sealing body 17, the formation of the flash/burrs on the lower surface 12L of the die pad 12 can be suppressed.

It is understood that the foregoing description and accompanying drawings set forth the preferred embodiments of the present disclosure at the present time. Various modifications, additions and alternative designs will, of course, become apparent to those skilled in the art in light of the foregoing teachings without departing from the spirit and scope of the disclosed disclosure. Thus, it should be appreciated that the present disclosure is not limited to the disclosed Examples but may be practiced within the full scope of the appended claims. The present application is based upon and claims the benefit of priority from the prior Japanese Patent Application No. 2023-165987 filed on Sep. 27, 2023, the entire contents of which are incorporated herein by reference.

### DESCRIPTION OF REFERENCE SIGNS

100, 110, 120 Semiconductor device
11 Lead frame
12 Die pad
13 Lead
15 Semiconductor chip
17 Sealing body
21 Mold

What is claimed is:

1. A semiconductor device comprising:
a lead frame including a plate-shaped die pad and a lead, the die pad having one principal surface with a mounting region for mounting a semiconductor chip, the die pad including a side portion and a frame-shaped protrusion on the side portion in top view, the protrusion overhanging in a lateral direction in an eave shape along the one principal surface;
the semiconductor chip mounted on the mounting region; and
a sealing body covering a side surface of the die pad while exposing the other principal surface of the die pad and sealing the semiconductor chip on the one principal surface of the die pad, the sealing body holding the die pad and the lead, wherein
the die pad has a through hole penetrating the protrusion in a direction intersecting with the one principal surface.

2. The semiconductor device according to claim 1, wherein
the through hole is formed so as to penetrate a portion of a base of the protrusion.

3. The semiconductor device according to claim 2, wherein
the through hole includes a notch portion terminating without reaching the other principal surface of the die pad from a portion inside the base of the protrusion of the one principal surface of the die pad.

4. The semiconductor device according to claim 1, wherein
the through hole penetrates the protrusion in a direction perpendicular to the one principal surface.

5. The semiconductor device according to claim 1, wherein
the plurality of through holes are formed along an outer edge of the semiconductor chip in a top view of the one principal surface viewed from above.

6. The semiconductor device according to claim 5, wherein
the semiconductor chip has a rectangular upper surface shape, and
the through hole has a rectangular shape with a longitudinal direction along each side of the semiconductor chip.

7. The semiconductor device according to claim 5, wherein
the semiconductor chip has a rectangular upper surface shape, and
the through hole has a rectangular shape with a longitudinal direction perpendicular to a direction along each side of the semiconductor chip.

8. The semiconductor device according to claim 1, wherein
the semiconductor chip has a rectangular upper surface shape, and
the through hole has a rectangular shape with a longitudinal direction along each side of the semiconductor chip, and a length of the longitudinal direction is a same as a length of a side of the semiconductor chip.
